(19) United States
(12) Patent Application Publication
(10) Pub. No.: US 2011/0284268 A1
(43) Pub. Date: Nov. 24, 2011

(54) FLEXIBLE CIRCUIT COVERFILM ADHESION ENHANCEMENT

(75) Inventors: RAVI PALANISWAMY, Singapore (SG); FONG LIANG TAN, Singapore (SG); RONALD L. IMKEN, Round Rock, TX (US); ROBIN E. GORRELL, Cedar Park, TX (US)

(73) Assignee: 3M Innovative Properties Company

(21) Appl. No.: 13/102,214

(22) Filed: May 6, 2011

Related U.S. Application Data
(60) Provisional application No. 61/346,538, filed on May 20, 2010.
(60) Provisional application No. 61/389,771, filed on Oct. 5, 2010.
(60) Provisional application No. 61/434,689, filed on Jan. 20, 2011.

(51) Int. Cl. H05K 1/02; B32B 38/14; B31B 1/62

(52) U.S. Cl. 174/251; 156/60; 156/277

(57) ABSTRACT

Provided is a means of improving the adhesion between a flexible circuit coverfilm and an encapsulant material in an inkjet printer application.

### CROSS REFERENCE TO RELATED APPLICATION

This application claims the benefit of U.S. Provisional Patent Application Nos. 61/346,538, filed May 20, 2010, 61/389,771, filed Oct. 5, 2010, and 61/434,689, filed Jan. 20, 2011, the disclosure of which is incorporated by reference herein in its entirety.

### TECHNICAL FIELD

This invention relates to improving the adhesion between a flexible circuit coverfilm and an encapsulant material in an inkjet printer application.

### BACKGROUND

In various applications, flexible circuits may be exposed to corrosive materials. In such applications, it is desirable to protect the flexible circuit with a protective covercoat or coverlayer. One such application is inkjet printer pens.

Inkjet printer pens are cartridges installed in inkjet printing systems for storing and dispensing ink onto recording media (e.g., paper). An inkjet printer pen typically includes a pen body for retaining the ink, a printer chip disposed on the pen body for dispensing the ink, and a flexible circuit attached to the body for electrically interconnecting the printing system and the printer chip. During a printing operation, the printing system transmits an electrical signal through the flexible circuit to the printer chip. The signal causes the ink to eject from the pen body onto the recording medium based on the jetting technique used. For example, thermal bubble jetting uses a resistive component that heats up when the electrical signal is received from the printing system. This causes a portion of the ink to volatilize to create a bubble that ejects ink from the pen body. Alternatively, piezoelectric jetting uses a transducer that mechanically ejects ink from the pen body when the electrical signal is received.

If the conductive components of the flexible circuit are not completely encapsulated with an ink-resistant material, the ink, which typically contains corrosive solvents, may chemically attack the conductive components. This may result in electrical shorts and poor signals, which can render the printer pen inoperable.

### SUMMARY

In at least one aspect, this invention relates to the roughening of coverlayer coverfilms used on inkjet flexible circuits as a means of increasing adhesion to encapsulant materials, thereby increasing inkjet pen reliability. This roughening may be accomplished by a number of approaches such as the following: embossing the coverfilm with a textured metal layer (removed by etching), microreplication, or chemical roughening of the coverfilm.

One embodiment of the invention provides an article comprising a flexible circuit having a substrate layer, a patterned conductive circuit on the substrate layer, and a coverlayer on the conductive circuit comprising a coverfilm adhered to the conductive circuit with an adhesive layer wherein the surface of the coverfilm opposite the adhesive layer is textured.

Another embodiment of the invention provides a method comprising: providing a flexible circuit having a substrate layer and a patterned conductive circuit on the substrate layer, and applying a coverlayer onto the conductive circuit, the coverlayer comprising a coverfilm adhered to the conductive circuit with an adhesive layer wherein the surface of the coverfilm opposite the adhesive layer is textured.

Another embodiment of the invention provides an article comprising a flexible circuit having a substrate layer, a patterned conductive circuit on the substrate layer, and a coverlayer on the conductive circuit comprising a coverfilm adhered to the conductive circuit with an adhesive layer wherein the surface of the coverfilm opposite the adhesive layer comprises a thermoplastic polyimide material.

The above summary of the present invention is not intended to describe each disclosed embodiment or every implementation of the present invention. The Figures and detailed description that follow below more particularly exemplify illustrative embodiments.

### BRIEF DESCRIPTION OF DRAWINGS

FIG. 1 depicts an encapsulated connection between an inkjet die and a flexible circuit.

FIG. 2 depicts the structure of UPISEL-N material.

FIG. 3 is a digital image of an embodiment of a thermoplastic polyimide coverfilm surface of the present invention after a laminated roughened copper foil has been etched away.

FIG. 4 depicts an exemplary microreplication process for texturing the surface(s) of a coverfilm of an embodiment the present invention.

FIG. 5 is a digital image of an embodiment of a chemically etched thermoplastic polyimide coverfilm surface of the present invention.

FIG. 6 is a digital image of another embodiment of a chemically etched thermoplastic polyimide layer coverfilm surface of the present invention.

FIGS. 7a and 7b depict polyimide coverlayers in which the coverfilm portion has one or both surfaces covered by a heat fusible thermoplastic polyimide layer.

FIG. 8 is a digital image of the results of shear tests of examples of the invention and comparative examples.

### DETAILED DESCRIPTION

In the following detailed description of the preferred embodiments, reference is made to the accompanying drawings that form a part hereof. The accompanying drawings show, by way of illustration, specific embodiments in which the invention may be practiced. It is to be understood that other embodiments may be used, and structural or logical changes may be made without departing from the scope of the present invention. The following detailed description, therefore, is not to be taken in a limiting sense, and the scope of the invention is defined by the appended claims.

Inkjet printheads intended for long life performance using flexible circuits to provide electrical interconnection between the inkjet die and printing system require robust protective layers on the flexible circuit. This robust construction is needed because of the corrosive ink environment, elevated temperatures, and mechanical wiping action associated with printhead function. Coverlayer materials, having adhesive and coverfilm layers, are recognized solutions for the demands of long life printheads because the coverfilm provides a significant degree of protection from abrasion and chemical attack. Popular coverfilms include, but are not limited to, polyimide, polyethylene naphthalate, and polyaramid. Adhesives used in these coverlayer materials include a wide variety of chemistries including, but not limited to, polyamide-phenolics, epoxidized styrene-butadienes, acrylates, and epoxies. The adhesives may be crosslinked or uncrosslinked. One suitable type of adhesive is the thermoset crosslinked adhesive described in U.S. Pat. App. No. 2007-0165076, incorporated herein by reference. Another suitable type of adhesive is the polyamide based adhesives described in U.S. Pat. No. 5,707,730, the following portions of which are incorporated herein by reference: col. 3, line 10 to col. 4, line 21; col. 5, lines 1-11, 33-43, and 53-63; and col. 6, lines 6-15 and 46-56. Particularly suitable polyamide based adhesives include those made with the following components by the method described below. A mixture is formed of (a) 300 to 500 parts of a 25 wt % polyamide resin solution in isopropyl alcohol/toluene mixed solvent, having a molecular weight of 28,000-44,000 and amine value of 2-55 (for example those available under the trade designation “TOHMIDE 394, 535, 1350 & 1360” from Fji Kasei Kogyo K. K., Japan); (b) 100 parts epoxy resin (for example bis-phenol A based epoxy resin available under the trade designation EPIKOTE 828 from Yuka Shell Epoxy K.K., Japan); (c) 30 parts of a 50 wt % novolak phenolic resin solution in methy ethyl ketone (for example those available under the trade designation CKM2432 from Showa Kobunshi K. K., Japan); and (d) 0.3 parts of a 1 wt % 2-methylimidazole solution in methyl ethyl ketone.

The mixture of the above components can be coated on to a release liner, e.g., a PET liner, to a required thickness and dried at temperatures of 100-200° C. for 2 min. The adhesive can then be subjected to an ageing process at 60° C. for 24-96 hours to create a semi-cured thermosetting stage. The resultant film can then be laminated onto, e.g., a polyimide film (for example those available under the trade designations of UPILEX SN, UPILEX CA and UPILEX VT available from UBE, Japan).

The coverlayers may be any thickness suitable for the intended application. In some embodiments, suitable thicknesses for the coverlayers range from a lower value of about 30 to about 40 micrometers and an upper range of about 50 to about 80 micrometers. The coverfilm may be any suitable thickness, but is typically about 12 to about 25 micrometers thick. The adhesive film desirably has a layer thickness sufficient to encapsulate the conductive traces of the flexible circuit to which it is attached and provide good adhesion between the flexible circuit and coverfilm. The layer thickness of the adhesive film is generally dependent on the layer thicknesses of the conductive traces, which may range from about 1 micrometer to about 100 micrometers. Typical layer thicknesses for conductive traces of commercial inkjet printer cartridges range from about 25 micrometers to about 50 micrometers. Suitable layer thicknesses for the adhesive layer are typically at least about 1 to 2 times the layer thickness of conductive traces, with particularly suitable layer thicknesses being at least about 1.5 times the layer thickness of conductive traces.

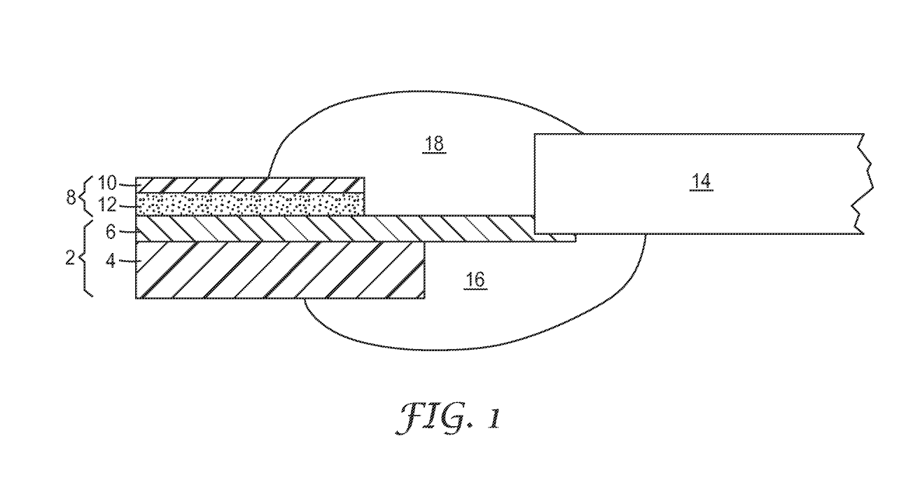

Subsequent to attachment of the flexible circuit to the printer chip, additional protection is needed to insure that ink is excluded from active electrical connections. This is typically provided by an encapsulant or sealant which covers exposed metal traces on the flexible circuit as well as connection points on the thermal inkjet die. This encapsulant material is applied after electrical connection is made between the flexible circuit and thermal inkjet die. It is dispensed on both sides of the flex-die structure and cured. FIG. 1 illustrates an encapsulated connection. Flexible circuit 2 includes substrate 4 and circuit layer 6. Circuit layer 6 is partially protected by coverlayer 8, which includes coverfilm 10 and adhesive 12. The exposed end of circuit layer 6 makes electrical connection with inkjet die 14. Topside encapsulant material 16 is applied such that it covers one side of the exposed end of circuit layer 6 as well as adjacent portions of substrate 4 and inkjet die 14. Backside encapsulant material 18 is applied such that it covers the other side of the exposed end of circuit layer 6 as well as adjacent portions of coverlayer 8 and inkjet die 14.

A common source of failure in these encapsulation systems is a loss of adhesion between the encapsulant material and the coverfilm 10 of the coverlayer 8. This is typically due to 1) the chemical inertness of the coverfilm, which inhibits chemical bonding between the coverfilm and the encapsulant and 2) the smoothness of the coverfilm, which provides relatively little surface area of contact for bonding to the encapsulant. Delamination between the coverfilm and encapsulant allows corrosive ink to penetrate to the electrical connections leading to copper corrosion, delamination of the coverlayer from the flexible circuit, and electrical shorting within the circuitry and/or between the circuitry contact points on the thermal inkjet die.

The inventors found that having a roughened or textured surface on the coverfilm, which is bonded to the encapsulant material, provides for additional surface area of contact, hence higher adhesion and less opportunity for delamination of the encapsulant from the coverfilm. The texture of the surface may have a random pattern or a uniform pattern. The heights of any depressions or protrusions of the texture may be uniform or varied. The roughened or textured surface of the coverfilm may have an average peak to valley distance of between about 5 to about 0.5 micrometers, typically about 1 to about 3 micrometers. This roughening can be achieved in several ways including the following:

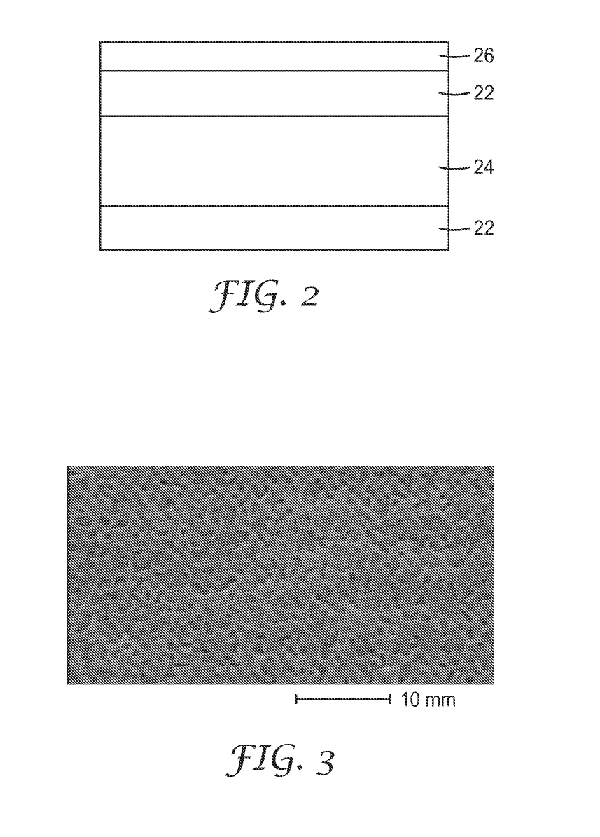

1) Use of a coverfilm that has a rough surface texture as a result of previous bonding to a roughened metal substrate. One such coverfilm that the inventors found to demonstrate enhanced encapsulant adhesion is available under the trade designation UPISEL-N from Ube Industries, Ltd., Specialty Chemicals & Products, Japan. This material has a total thickness of about 12 to about 15 micrometers that consists of a thermoset polyimide core clad on each side with a thin thermoplastic polyimide (TPPI) layer having a thickness of about 2 to about 3 micrometers (the material is commercially available as UPILEX VT polyimide from Ube Industries, Ltd., Specialty Chemicals & Products) which has been subsequently heat-laminated to roughened copper foil on one or both sides to create the UPISEL-N product. FIG. 2 illustrates the structure of a UPISEL-N product with its thermoplastic polyimide (TPPI) layers 22, thermoset polyimide core layer 25 and copper foil layer 26. The inventors found that by etching the copper away from the TPPI layer, a “fingerprint” of the roughened copper remains in the TPPI layer which significantly increases the surface area for contact with an encapsulant. The amount of the roughness can be established by the roughness of the copper foil which is laminated to the thermoplastic polyimide layers. A typical TPPI surface resulting from the etching of copper foil from a UPISEL-N substrate is shown in FIG. 3. The copper can be etched with a number of conventional and commercially-available chemistries such as CuCl₂+HCl, H₂SO₄+H₂O₂, FeCl₃+HCl, or H₂SO₄+Na₂S₂O₈.

An additional option with this approach would include “3-layer” substrates in which a thermoset adhesive layer is used to bond a base polyimide substrate to a copper foil. An example of such a substrate is an epoxy-based adhesive system used in combination with copper and KAPTON polyimide, commercially available as NIKAFLEX laminates from DuPont, USA. In this case, the copper could be etched away to expose the thermoset adhesive, which will have the negative image of the copper foil to which it was bonded. If the copper foil does not impart the desired level of roughness to the thermoset adhesive, the thermoset adhesive may be further treated by methods known in the art to impart the desired roughness.

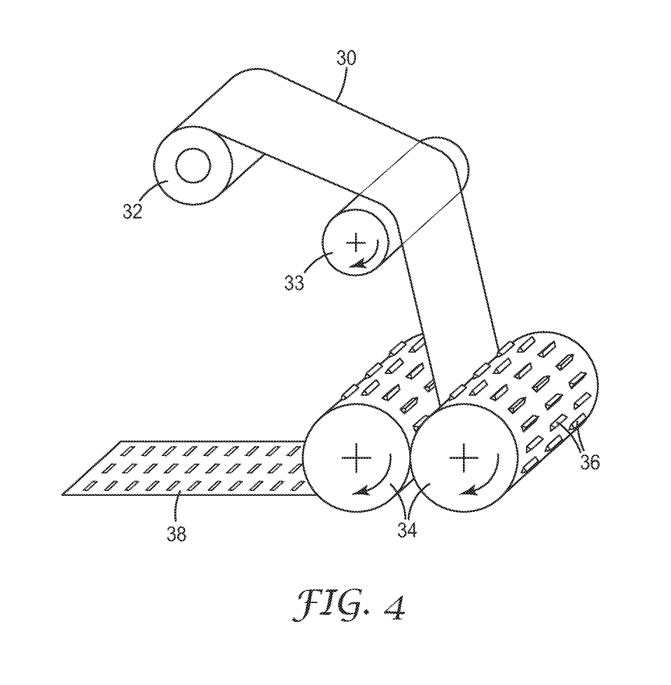

2) Use of a film such as UPILEX VT or other suitable films, the outer surfaces of which have been textured with embossing techniques, such as the one illustrated in FIG. 4, or microreplication techniques to produce a larger surface area on one or both sides of the film. FIG. 4 shows an embossing process in which a film 30 to be embossed is unwound from wind-up roll 32, passed over a guiding roll 33 and between embossing rolls 34 and 36, which both have protrusions on their surfaces. Embossing rolls 34 and 36 are typically heated so that film 30 will soften and take on the negative shape of the protrusions of the embossing rolls 34 and 36 as it passes between them, thereby producing embossed film 38, which will have protrusions and depressions on both surfaces. To create protrusions only on one side of the film (and depressions on the other side of the film) one of the rolls can have a smooth surface.

3) Chemical etching of the outer layer(s) of a film such as UPILEX VT or other suitable films, to produce an enhanced topography for bonding to the encapsulant. An example of a suitable etching solution for the thermoplastic polyimide outer layer of the UPILEX VT is an aqueous solution comprising an alkali metal salt, a solubilizer, and ethylene glycol. A suitable alkali metal salt is potassium hydroxide (KOH), sodium hydroxide (NaOH), substituted ammonium hydroxides, such as tetramethylammonium hydroxide and ammonium hydroxide or mixtures thereof. Typical concentrations of a suitable salt have lower values of about 30 wt. % to about 40 wt % and upper values of about 50 wt % to about 55 wt. %. Suitable solubilizers for the etching solution may be selected from the group consisting of amines, including ethylene diamine, propylene diamine, ethylamine, methylethylamine, and alkanolamines such as ethanolamine, monoethanolamine, diethanolamine, propanolamine, and the like. Typical concentrations of a suitable solubilizer have lower values of about 10 wt. % to about 15 wt. % and upper values of about 30 wt. % to 35 wt. %. Typical concentrations of ethylene glycol, e.g., monoethylene glycol, have a lower value of about 3 wt % to about 7 wt % and an upper value of about 12 wt % to about 15 wt %.

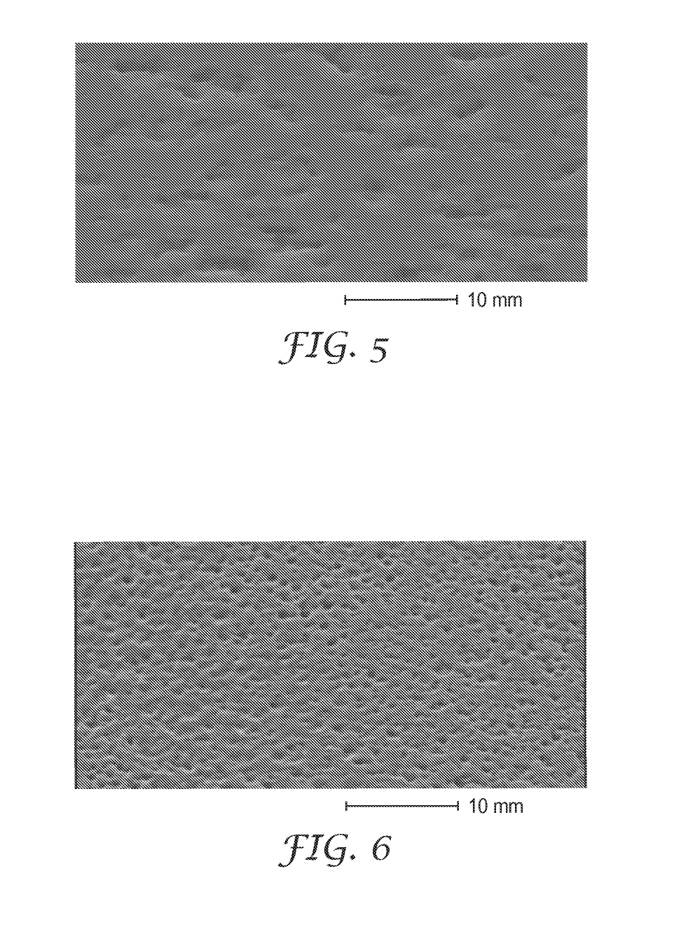

In at least one instance a suitable etching solution comprises about 45 to about 42 wt % KOH, about 18 to about 20 wt % monoethanol amine (MEA), and about 3 to about 15 wt % monoethylene glycol (MEG). An additional benefit to this approach is the chemical activation of the polyimide surface by converting polyimide groups to polyamic acid. This functionalization of the polyimide surface provides reactive groups for covalent bonding with some encapsulant chemistries. An example of UPILEX VT surface etched with about 45 wt % KOH at about 200° F. (93° C.) at a line speed of about 140 cm/min. is shown in FIG. 5 and with about 42-43 wt % KOH, about 20-21 wt % MEA, and about 6-7 wt % MEG at about 200° F. (93° C.) in a beaker for about one minute is shown in FIG. 6.

The inventors have found that the encapsulant adhesion with a coverfilm is largely dependent on 1) the roughness of the coverfilm which provides relatively higher surface area for contact with the encapsulant material, as described above, and/or 2) the inherent properties of the coverfilm surface which provides either chemical bonding or a physical interactions such as hydrophobic or ionic interactions etc. with the encapsulant material.

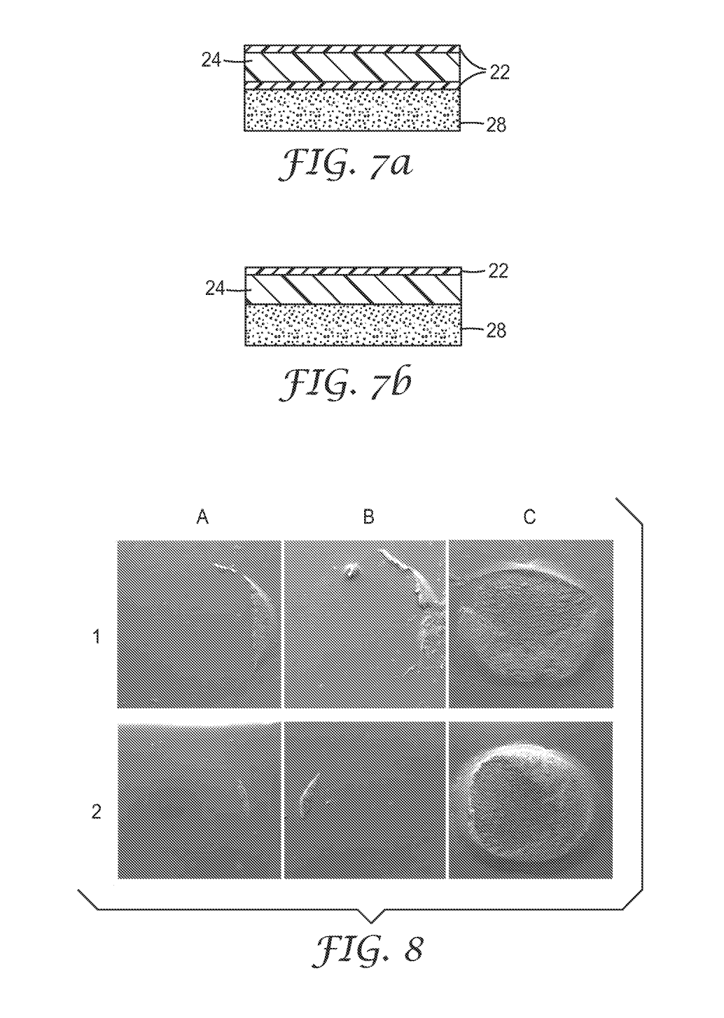

With respect to inherent properties, the inventors found UPILEX VT film, even without any surface roughening or surface treatment, provided superior adhesion to encapsulant material as compared to films such as UPILEX SN and UPILEX CA. It is believed that this is due to the presence of the heat fusible thermoplastic polyimide (TPPI) on the surface of the UPILEX VT films. It is believed that the thermoplastic nature of the TPPI layer allows for the possibility that the encapsulant material forms an interpenetrating polymer network (IPN) with the TPPI layer during cure, resulting in a transition layer consisting of a mixture of both materials. This transition layer inhibits interfacial adhesion failures which would typify surfaces with no mixing. Thermoset materials, such as those associated with UPILEX SN and UPILEX CA provide for less molecular mobility and swelling such that penetration of an encapsulant into the layer would be more difficult. Accordingly, another embodiment of the present invention includes a coverfilm having a TPPI layer at least on the surface of the coverfilm that will be adhered to the encapsulant material and, optionally, also on the surface that will be adhered to the adhesive layer of the coverlayer. These embodiments are illustrated in FIGS. 7a and 7b which illustrate coverlayers having heat fusible TPPI layers 22, thermoset polyimide layers 24, and adhesive layers 28.

### EXAMPLES

This invention is illustrated by the following examples, but the particular materials and amounts thereof recited in these examples, as well as other conditions and details should not be construed to unduly limit this invention.

To demonstrate at least one aspects of the invention, UPILEX VT film (15 um thickness) was procured from UBE-Nitto Kesai Co. Ltd., Japan for use as a coverfilm and coated with ELEPHANE CL-X adhesive, obtained from Tomoegawa, Japan, to form a coverlayer. The coverlayer was subjected to an encapsulant adhesion test on the coverfilm side as follows:

A drop of 3M epoxy 1735 encapsulant was applied on approximately 1 mm of the exposed surface of the UPILEX VT film and the coverlayer was cured in an oven at 130° C. for 30 min. Comparative examples were made in the same manner but with UPILEX SN and UPILEX CA as the coverfilm instead of UPILEX VT.

The prepared samples (including the comparative samples) were subjected to the following shear test prior to being soaked in ink: The samples were bonded on to a glass surface with LOCTITE 380 instant adhesive (black) and left to set for at least 3 hrs. The shear test was performed with Dage Shear Tester by applying a shear speed of 30 um/sec & a height of 1 um. Then the diameter of the encapsulant sheared off of the sample surface was measured.

All the samples were subjected to ink soak test by soaking in a solvent-based alkaline ink having a pH of about 8-9 in a very tight container and kept at 75° C. for 7 days.

The samples were removed periodically and subjected to the shear test described above after the following preparations steps were taken: The ink soaked samples were removed and rinsed with deionized (DI) water and dried for at least 3 hrs.

FIG. 8 shows the results of the shear test before ink soaking (Row 1) and after ink soaking (Row 2) at 75° C. for 7 days for UPILEX SN (Column A), UPILEX CA (Column B), and UPILEX VT (Column C). As FIG. 8 shows, the shear test on the coverlayer made with the UPILEX VT coverfilm with and without ink soak showed cohesive failure mode in that the failure was within the encapsulant layer instead of at the interface of the encapsulant and polyimide layers and the coverlayers made with the UPILEX SN and UPILEX CA coverfilms showed adhesive failure at the interface of the encapsulant and polyimide layers. The cohesive failure mode within the encapsulant indicates the stronger adhesion between the encapsulant and the TPPI layer of the UPILEX VT film as compared to the adhesion between the encapsulant and the thermoset or chemically-treated thermoset outer material in the UPILEX SN and UPILEX CA films.

Once it has been prepared, by whatever means, the coverfilm is typically laminated to an adhesive film to form the coverlayer.

The approaches identified above provide a means of significantly enhancing encapsulant-to-coverfilm adhesion without impacting the basic flexible circuit manufacturing process. Any coverfilm surface area modifications are made prior to coverlayer manufacture (adhesive coating on coverfilm) so that coverlayer lamination to the copper-polyimide circuit is not impacted. Having a TPPI surface layer on the outward-facing surface of the coverfilm portion of the coverlayer may be achieved before or after adhesive coating the coverfilm, but is preferably done before such coating.

Although specific embodiments have been illustrated and described herein for purposes of description of the preferred embodiment, it will be appreciated by those of ordinary skill in the art that a wide variety of alternate and/or equivalent implementations may be substituted for the specific embodiments shown and described without departing from the scope of the present invention. This application is intended to cover any adaptations or variations of the preferred embodiments discussed herein. Therefore, it is manifestly intended that this invention be limited only by the claims and the equivalents thereof.

What is claimed is:

1. An article comprising:
a flexible circuit having a substrate layer,
a patterned conductive circuit on the substrate layer, and
a coverlayer on the conductive circuit comprising a coverfilm adhered to the conductive circuit with an adhesive layer wherein the surface of the coverfilm opposite the adhesive layer is textured.

2. The article of claim 1 wherein the textured surface of the coverfilm has a random pattern.

3. The article of claim 1 wherein the textured surface of the coverfilm has a uniform pattern.

4. The article of claim 1 wherein the textured surface of the coverfilm has an average peak to valley distance of about 1 to about 3 micrometers.

5. The article of claim 1 wherein the textured surface of the coverfilm is adhered to an inkjet printer encapsulant material.

6. The article of claim 5 wherein the coverfilm and encapsulant material form an interpenetrating network at their interface.

7. The article of claim 1 wherein the coverfilm comprises a thermoset polyimide core clad on each side with a thin thermoplastic polyimide layer.

8. A method comprising:
providing a flexible circuit having a substrate layer and a patterned conductive circuit on the substrate layer, and
applying a coverlayer onto the conductive circuit, the coverlayer comprising a coverfilm adhered to the conductive circuit with an adhesive layer wherein the surface of the coverfilm opposite the adhesive layer is textured.

9. The method of claim 8 wherein the coverfilm surface is textured by heat laminating a roughened copper foil to the coverfilm, followed by etching away the copper foil.

10. The method of claim 8 wherein the coverfilm surface is textured by microreplication.

11. The method of claim 8 wherein the coverfilm surface is textured by embossing.

12. The method of claim 8 wherein the coverfilm surface is textured by chemical etching.

13. The method of claim 8 further comprising applying an inkjet printer encapsulant material onto the textured surface of the coverfilm.

14. The article of claim 13 wherein the encapsulant material and the coverfilm form an interpenetrating network at their interface.

15. An article comprising:
a flexible circuit having a substrate layer,
a patterned conductive circuit on the substrate layer, and
a coverlayer on the conductive circuit comprising a coverfilm adhered to the conductive circuit with an adhesive layer wherein the surface of the coverfilm opposite the adhesive layer comprises a thermoplastic polyimide material.

16. The article of claim 15 wherein the coverfilm comprises a thermoset polyimide core clad on each side with a thermoplastic polyimide layer.

17. The article of claim 15 wherein the adhesive comprises polyamide resin.

18. The article of claim 15 wherein the adhesive comprises polyamide resin, epoxy resin, and novolak phenolic resin.

19. The article of claim 15 wherein the thermoplastic polyimide material of the coverfilm is adhered to an inkjet printer encapsulant material.

20. The article of claim 15 wherein the thermoplastic polyimide material and encapsulant material form an interpenetrating network at their interface.
